(19) United States
(12) Patent Application Publication
(10) Pub. No.: US 2024/0019541 A1
(43) Pub. Date: Jan. 18, 2024

(54) APPARATUS FOR EVALUATING RADAR PERFORMANCE

(71) Applicant: HYUNDAI MOBIS CO., LTD., Seoul (KR)

(72) Inventors: Tae Yun LEE, Yongin-si (KR); Do Yun KIM, Yongin-si (KR)

(73) Assignee: HYUNDAI MOBIS CO., LTD., Seoul (KR)

(21) Appl. No.: 18/220,520

(22) Filed: Jul. 11, 2023

(30) Foreign Application Priority Data
Jul. 12, 2022 (KR) 10-2022-0085963

(51) Int. Cl. G01S 7/40

(52) U.S. Cl. CPC G01S 7/4086; G01S 7/40

(57) ABSTRACT

An apparatus for evaluating radar performance according to the present disclosure includes a chamber part having a hollow shape having a space therein, a radar installed on a first inner surface of the chamber part, and at least one reflector part installed on a second inner surface of the chamber part and configured to reflect radio waves emitted from the radar.

### CROSS-REFERENCE TO RELATED APPLICATION

This application claims the benefit of priority under 35 USC § 119(a) to Korean Patent Applications No. 10-2022-0085963, filed on Jul. 12, 2022, the entire disclosure of which is incorporated herein by reference for all purposes.

### BACKGROUND

### Field

Exemplary embodiments of the present disclosure relate to an apparatus for evaluating radar performance, and more particularly, to an apparatus for evaluating radar performance, which is capable of reducing the time required to evaluate performance of radar and reducing component costs and noise.

### Discussion of the Background

In general, a radar is mounted in a vehicle or the like and used to measure distances, velocities, and angles with respect to surrounding objects. Because performance of the radar needs to be evaluated, a test is performed on the radar installed in a chamber to measure performance such as power, signal-to noise radio (SNR), velocities, distances, and angles of the radar. In this case, the radar is mounted on a rotator rotatably installed in the chamber, and the rotator is operated to perform the test to measure the performance of the radar.

However, because the rotator is operated to perform the test to measure the performance of the radar, the time for operating the rotator is required, which causes a problem in which the amount of time required to measure the performance of the radar increases, and noise occurs when the rotator operates.

In addition, the rotator is made of a metallic material and occupies the largest volume in the chamber, which causes a problem in which the rotator limits the design of the chamber. Accordingly, there is a need to solve the problem.

The background technology of the present disclosure is disclosed in Korean Patent No. 10-2124068 (registered on Jun. 11, 2020 and entitled ‘Apparatus and Method for Evaluating Performance of FMCW Radar Proximity Sensor’).

### SUMMARY

Various embodiments are directed to an apparatus for evaluating radar performance, which is capable of reducing the time required to evaluate performance of a radar and reducing component costs and noise.

In an embodiment, an apparatus for evaluating radar performance includes: a chamber part having a hollow space therein; a radar installed on a first inner surface of the chamber part; and at least one reflector part installed on a second inner surface of the chamber part and configured to reflect radio waves emitted from the radar.

The chamber part may be formed in a polyhedral shape.

The reflector parts may be provided as a plurality of reflector parts, and the reflector parts may be installed at different positions on the inner surface of the chamber part.

When an angle, which is defined by a longitudinal axis at a point, at which the radar is installed, and an imaginary line, which connects the radar and the at least one reflector part, is defined as a preset angle, the plurality of reflector parts may have different preset angles.

In a circumferential direction with respect to the Z-axis on the radar, the at least one reflector part may be positioned at one of points at which the imaginary lines, which run through the preset angles defined by the Z-axis and the radio waves emitted from the radar, meet the chamber part.

When a distance from the radar to the at least one reflector part is defined as a preset distance, the plurality of reflector parts may have different preset distances.

The preset distance r from the radar to the at least reflector part is within a distance range determined based on a formula of rₘᵢₙ≤nL±L/4≤rₘₐₓ, wherein rₘᵢₙ, is a minimum value of the preset distance r, and rₘₐₓ, is a maximum value of the preset distance r, n is constant multiples, L is distance resolution.

The distance resolution L is determined based on the formula of L≥C₀/2BWₜₓ, wherein C₀ represents a velocity of light and BW represents a band width of the radar.

The reflector part may have a hemispherical reflector.

The apparatus for evaluating radar performance according to the present disclosure may further include: a simulation part installed on the inner surface of the chamber part that faces the first inner surface, the simulation part being configured to receive the radio waves from the radar and emit radio waves modified by a predetermined value.

The apparatus for evaluating radar performance according to the present disclosure may further include: an absorbent installed on the inner surface of the chamber part and configured to absorb radio waves emitted from at least one of the radar, the at least one reflector part, and the simulation part.

The apparatus for evaluating radar performance according to the present disclosure may further include: the absorbent installed on the second inner surface of the chamber part.

The apparatus for evaluating radar performance according to the present disclosure may further include: the absorbent including a concave-convex surface having quadrangular pyramidal shapes repeatedly disposed.

The apparatus for evaluating radar performance according to the present disclosure may further include: the radar disposed on the first inner surface and symmetric in a circumferential direction of the apparatus in a longitudinal axis of the apparatus.

The apparatus for evaluating radar performance according to the present disclosure may further include: a simulation part installed on a portion of the second inner surface of the chamber part that faces the radar mounted on the first inner surface in the longitudinal axis on the radar.

The apparatus for evaluating radar performance according to the present disclosure may further include: an absorbent installed on the inner surface of the chamber part and configured to absorb radio waves emitted from at least one of the radar, the at least one reflector part, and the simulation part.

The apparatus for evaluating radar performance according to the present disclosure may further include: an absorbent installed on the inner surface of the chamber part and configured to absorb radio waves emitted from at least one of the radar and the at least one reflector part.

The apparatus for evaluating radar performance according to the present disclosure measures the performance of the radar by using the plurality of reflector parts. Therefore, it is possible to reduce the time required to measure the performance of the radar, reduce component costs, and prevent the occurrence of noise during the process of measuring the performance of the radar, in comparison with the related art that measures performance of radar by operating a rotator.

In addition, according to the present disclosure, the rotator need not be installed in the chamber part, unlike the related art. Therefore, it is possible to improve a degree of freedom related to the shape of the chamber part.

### BRIEF DESCRIPTION OF THE DRAWINGS

FIG. 1 is a perspective view of an apparatus for evaluating radar performance according to an embodiment of the present disclosure.

FIG. 2 is a front view of the apparatus for evaluating radar performance according to the embodiment of the present disclosure.

FIG. 3 is a view illustrating positions of reflector parts in the apparatus for evaluating radar performance according to the embodiment of the present disclosure that are set based on orthogonal and polar coordinates.

FIG. 4 is a front view of FIG. 3.

### DETAILED DESCRIPTION OF THE ILLUSTRATED EMBODIMENTS

Hereinafter, an apparatus for evaluating radar performance will be described below with reference to the accompanying drawings through various exemplary embodiments.

Here, thicknesses of lines, sizes of constituent elements, or the like illustrated in the drawings, may be exaggerated for clarity and convenience of description. In addition, the terms used below are defined in consideration of the functions in the present disclosure and may vary depending on the intention of a user or an operator or a usual practice. Therefore, the definition of the terms should be made based on the entire contents of the present specification.

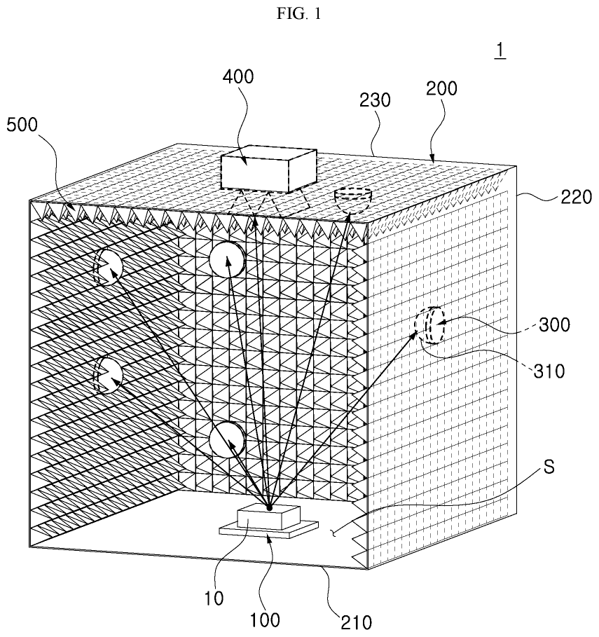

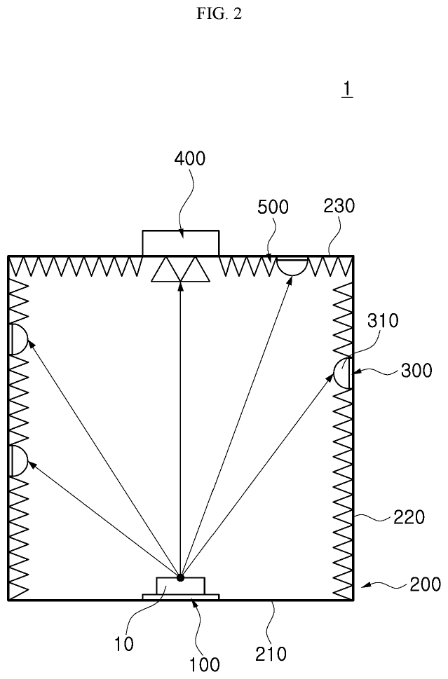

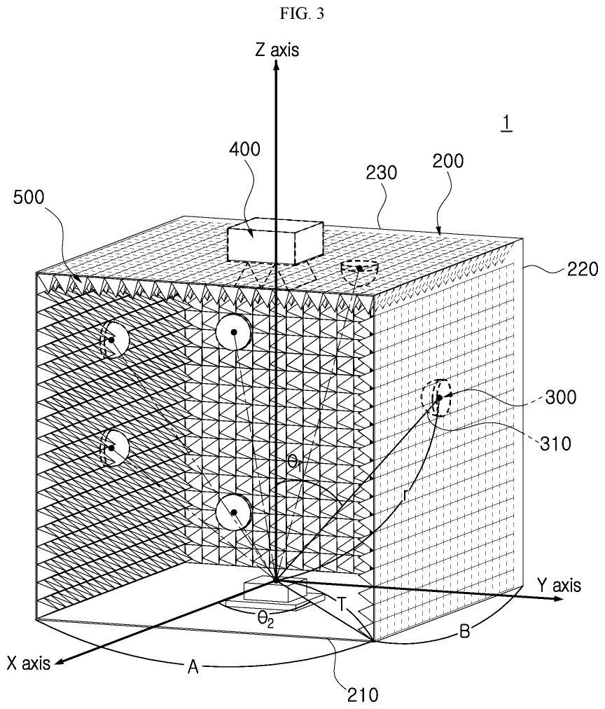

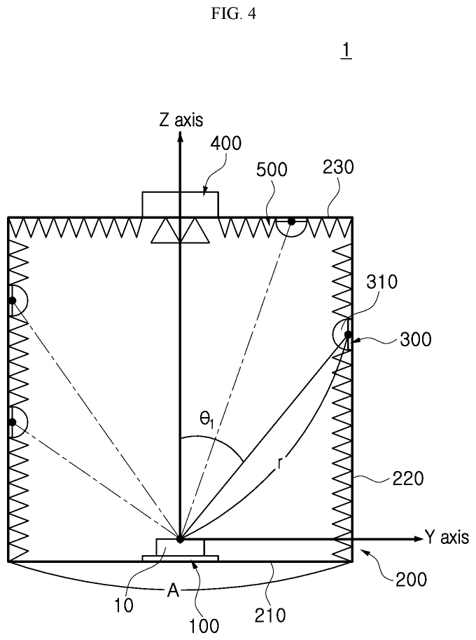

FIG. 1 is a perspective view of an apparatus for evaluating radar performance according to an embodiment of the present disclosure, FIG. 2 is a front view of the apparatus for evaluating radar performance according to the embodiment of the present disclosure, FIG. 3 is a view illustrating positions of reflector parts in the apparatus for evaluating radar performance according to the embodiment of the present disclosure that are set based on orthogonal and polar coordinates, and FIG. 4 is a front view of FIG. 3.

With reference to FIGS. 1 to 4, the apparatus 1 for evaluating radar performance according to the embodiment of the present disclosure includes a radar 10, a chamber part 200, and reflector parts 300.

The radar 10 may be installed on a jig part 100. The jig part 100 is installed on a chamber lower portion 210 of the chamber part 200, and the radar 10 is mounted on an upper surface of the jig part 100. The radar 10 may be an indoor radar with a short detection distance and a wide beam width. In addition to the indoor radar, various types of radars may be applied to the apparatus 1 for evaluating radar performance. The radar 10 may measure many areas in the chamber part 200 at once.

The jig part 100 is installed in the chamber part 200 and surrounds the radar 10. The chamber part 200 may have a polyhedral box shape and surround an outer side of the radar 10. The chamber part 200 may have a hollow box shape having a space S therein. In the present embodiment, the chamber part 200 is exemplarily described as having a hexahedral shape, but the shape of the chamber part 200 is not limited thereto.

The chamber part 200 may include the chamber lower portion 210, chamber sidewall portions 220, and a chamber upper portion 230. The chamber upper portion 230 may be disposed to face the chamber lower portion 210.

The jig part 100 may be installed on a central portion of an inner surface of the chamber lower portion 210, and the radar 10 may be mounted on the jig part 100. The inner surface of the chamber lower portion 210 may be defined as a first inner surface of the chamber part 200.

The chamber sidewall portions 220 are provided as a plurality of chamber sidewall portions 220. A lower end of the chamber sidewall portions 220 is connected to the chamber lower portion 210, and an upper end of the chamber sidewall portions 220 is connected to the chamber upper portion 230. The reflector parts 300 may be installed on inner surfaces of the chamber sidewall portions 220. The reflector part 300 reflects radio waves emitted from the radar 10.

The chamber sidewall portion 220 may be perpendicularly connected to the chamber lower portion 210. Of course, the chamber sidewall portion 220 may be disposed to be inclined with respect to the chamber lower portion 210.

The chamber upper portion 230 is connected to the upper ends of the plurality of chamber sidewall portions 220. The chamber lower portion 210, the chamber sidewall portions 220, and the chamber upper portion 230 may be connected to one another, such that the inside of the chamber part 200 may be closed.

The apparatus 1 for evaluating radar performance according to the embodiment of the present disclosure may further include a simulation part 400.

The simulation part 400 may be installed on a central portion of an inner surface of the chamber upper portion 230. The simulation part 400 may be installed on the inner surface of the chamber part 200 that faces the inner surface, i.e., the first inner surface of the chamber part 200 on which the radar 10 is installed.

In the present disclosure, because the reflector part 300 may be used to measure the performance of the radar 10, there is no limitation to the shape of the chamber part 200, unlike the related art using a rotator. Therefore, it is possible to improve a degree of freedom related to the shape of the chamber part 200.

In the present disclosure, the chamber part 200 is illustrated as having a box shape, but the shape of the chamber part 200 is not limited thereto. The shape of the chamber part 200 may be changed to various shapes such as a hemispherical shape within a range in which the reflector part 300 may measure the performance of the radar 10.

The at least one reflector part 300 may be installed on second inner surfaces of the chamber part 200. In this case, the second inner surfaces of the chamber part 200 are defined as inner surfaces of the chamber part 200 that exclude the first inner surface of the chamber part 200 on which the radar 10 is installed.

In the present embodiment, in case that the radar 10 is installed on the inner surface of the chamber lower portion 210, the reflector parts 300 may be installed on the inner surfaces of the chamber sidewall portion 220 and/or the inner surface of the chamber upper portion 230, except for the chamber lower portion 210.

The reflector parts 300 may be provided as a plurality of reflector parts 300. The reflector parts 300 may be installed at different positions on the inner surfaces of the chamber part 200.

Assuming that an angle defined between a longitudinal axis (Z-axis) at a point, at which the radar 10 is installed, and an imaginary line, which connects the radar 10 and the reflector part 300, is a preset angle θ1, the plurality of reflector parts 300 may have different preset angles θ1.

Assuming that a distance from the radar 10 to the reflector part 300 is a preset distance r, the plurality of reflector parts 300 may have different preset distances r. In addition, the plurality of reflector parts 300 may have different preset angles θ1 and different preset distances r.

The reflector parts 300 may be positioned at points at which imaginary lines, which run through the preset angles θ1, which are defined by the Z-axis, which is the longitudinal axis at the point at which the radar is installed, and the radio waves emitted from the radar 10, meet the chamber part 200. The preset distance r from the radar 10 to the reflector part 300 is within a distance range calculated on the basis of the formula of rₘᵢₙ≤nL±L/4≤rₘₐₓ (n: constant multiples, L: distance resolution).

With respect to the position of the reflector part 300 in a circumferential direction (based on FIG. 3) with respect to the Z-axis, the reflector part 300 may be positioned at one of the points at which the imaginary lines, which run through the preset angles θ1 defined by the Z-axis and the radio waves emitted from the radar 10, meet the chamber part 200. In this case, it can be seen that the radio waves emitted from the radar 10 define a conical shape having a width that increases as the distance from the radar 10 increases.

Assuming that the Z-axis has an angle of 0 degrees and angles of −90 degrees or more and 90 degrees or less may be set in a leftward/rightward direction (based on FIG. 4) with respect to the Z-axis, the preset angle θ1 may be any one angle of −90 degrees or more and 90 degrees or less.

Specifically, the preset angle θ1 may be a maximum angle of −90 degrees in the leftward direction (based on FIG. 4) with respect to the Z-axis and a maximum angle of 90 degrees in the rightward direction (based on FIG. 4) with respect to the Z-axis.

The position of the reflector part 300 may be selected on the basis of related formulas associated with orthogonal coordinates (x, y, z) and polar coordinates (r, θ₁, θ₂).

Specifically, the orthogonal coordinates (x, y, z) may be selected on the basis of the formulas of x=r sin θ₁ cos θ₂, y=r sin θ₁ sin θ₂, and z=r cos θ₁, and rₘᵢₙ, which is a minimum value of the preset distance r, and rₘₐₓ, which is a maximum value of the preset distance r, may be calculated on the basis of the formulas of α=arctan (A/B), −rₘᵢₙ=B/2 (sin θ₁ cos 0°)⁻¹, and −rₘₐₓ=T (sin θ₁ cos α)⁻¹.

After rₘᵢₙ, which is the minimum value of the preset distance r, and rₘₐₓ, which is the maximum value of the preset distance r, are calculated as described above, the preset distance r may be selected by inputting rₘᵢₙ and rₘₐₓ into the formula of rₘᵢₙ≤nL±L/4≤rₘₐₓ.

In this case, n represents constant multiples selected by calculating a value that satisfies the formula of rₘᵢₙ≤nL±L/4≤rₘₐₓ.

L represents distance resolution calculated based on the formula of L≥C₀/2BWₜₓ, C₀ represents a velocity of light, i.e., about 3×10⁸ m/s, and BW represents a band width. For example, in the case of the radar with the band width of 4 GHz, the distance resolution L is about 0.0375 m, i.e., about 3.75 cm. That is, the distance resolution L may be about 4 cm.

For example, in case that the position of the reflector part 300 is selected when θ₁ is +60 degrees, i.e., 60 degrees, A is 4 cm, and B is 4 cm, T may be 2√2, i.e., about 2.3 cm, and a may be 45 degrees. In this case, L may be about 4 cm.

In case that rₘᵢₙ is calculated on the basis of the formula of −rₘᵢₙ=B/2 (sin θ₁ cos0°)⁻¹, rₘᵢₙ may be about 1.05 cm. In case that rₘₐₓ is calculated on the basis of the formula of −rₘₐₓ=T(sin θ₁ cos α)⁻¹, rₘₐₓ may be about 14.03 cm.

n may be calculated as any one of 2 and 3, i.e., 1.05≤4n±4/4≤14.03 by applying the formula of rₘᵢₙ≤nL±L/4≤rₘₐₓ.

In this case, the reflector part 300 may be positioned at the point at which the imaginary line, which runs through the preset angle of 60 degrees defined by the Z-axis and the radio wave emitted from the radar 10, meets the chamber part 200, and the preset distance r may be within a range of 1.05 or more and 14.03 or less.

As described above, in the present disclosure, the preset distance r from the radar 10 to the reflector part 300 is within the distance range calculated on the basis of the formula of rₘᵢₙ≤nL±L/4≤rₘₐₓ (n: constant multiples, L: distance resolution). Therefore, on the basis of the radio wave emitted from the radar 10 and received by the reflector part 300, the radar 10 may accurately measure the measurement information of the reflector part 300 such as a height, an azimuth angle, and SNR of the reflector part 300.

The reflector part 300 has a hemispherical reflector 310. Because the reflector 310 has a hemispherical shape, the radar 10 may measure the point on the basis of the radio waves emitted from the radar 10 and received by the reflector 310 of the reflector part 300. That is, the radar 10 may measure the measurement information of the reflector part 300 as the point. Therefore, the radar 10 may more accurately measure the measurement information of the reflector part 300.

The simulation part 400 is installed in the chamber part 200, receives the radio waves from the radar 10, and emits radio waves modified by a predetermined value. Specifically, the simulation part 400 is a real-time simulator. The simulation part 400 may receive the radio waves from the radar 10 and emit radio waves modified by applying preset values to Doppler power.

The simulation part 400 is installed on the central portion of the chamber upper portion 230 of the chamber part 200 and faces the radar 10.

The apparatus 1 for evaluating radar performance according to the embodiment of the present disclosure may further include an absorbent 500.

The absorbent 500 may be installed on the inner surface of the chamber part 200 and absorb radio waves emitted from at least any one of the radar 10 and the reflector part 300. The absorbent 500 may absorb the radio waves emitted from the simulation part 400.

The absorbent 500 may be installed on the second inner surfaces of the chamber part 200. In this case, the second inner surfaces of the chamber part 200 are defined as the inner surfaces of the chamber part 200 that exclude the first inner surface of the chamber part 200 on which the radar 10 is installed. The absorbent 500 may be mounted over the entire surfaces of the chamber sidewall portion 220 and the chamber upper portion 230 of the chamber part 200 and have a concave-convex surface. The absorbent 500 may have a concave-convex surface having quadrangular pyramidal shapes repeatedly disposed.

The absorbent 500 is illustrated as having a concave-convex surface, but the present disclosure is not limited thereto. Therefore, the absorbent 500 may be made of various materials and have various shapes within a range in which the absorbent 500 may absorb the radio waves emitted from at least any one of the radar 10, the reflector part 300, and the simulation part 400.

The absorbent 500 may be mounted on the entire inner surfaces of the chamber sidewall portion 220 and the chamber upper portion 230 within a range in which the absorbent 500 does not prevent the reflector part 300 and the simulation part 400 from receiving the radio waves from the radar 10.

As described above, the apparatus 1 for evaluating radar performance according to the present disclosure measures the performance of the radar 10 by using the plurality of reflector parts 300, thereby reducing the time required to measure the performance of the radar 10 in comparison with the related art that measures performance of a radar by operating a rotator.

In addition, the apparatus 1 for evaluating radar performance according to the present disclosure may reduce component costs and prevent the occurrence of noise caused by the operation of the rotator during a process of measuring performance of the radar 10. In this case, the noise means abnormal sound and the like.

Further, unlike the related art, the rotator need not be installed in the chamber part 200. Therefore, the shape of the chamber part 200 may be freely configured to be suitable for situations, which may improve a degree of manufacturing freedom of the chamber part 200.

While the present disclosure has been described with reference to the embodiments depicted in the drawings, the embodiments are for illustrative purposes only, and those skilled in the art to which the present technology pertains will understand that various modifications of the embodiments and any other embodiments equivalent thereto are available.

Accordingly, the true technical protection scope of the present disclosure should be determined by the appended claims.

Although exemplary embodiments of the disclosure have been disclosed for illustrative purposes, those skilled in the art will appreciate that various modifications, additions and substitutions are possible, without departing from the scope and spirit of the disclosure as defined in the accompanying claims. Thus, the true technical scope of the disclosure should be defined by the following claims.

What is claimed is:

1. An apparatus for evaluating radar performance, the apparatus comprising:
a chamber part having a hollow space enclosed by an inner surface including a first inner surface and a second inner surface;
a radar installed on the first inner surface of the chamber part; and
at least one reflector part installed on the second inner surface of the chamber part and configured to reflect radio waves emitted from the radar.

2. The apparatus of claim 1, wherein the chamber part is formed in a polyhedral shape.

3. The apparatus of claim 1, wherein the at least one reflector part is provided as a plurality of reflector parts, and the reflector parts are installed at different positions on the second inner surface of the chamber part.

4. The apparatus of claim 3, wherein an angle, which is defined by a longitudinal axis at a point, at which the radar is installed, and an imaginary line, which connects the radar and the at least one reflector part, is defined as a preset angle and the plurality of reflector parts has different preset angles.

5. The apparatus of claim 4, wherein in a circumferential direction with respect to the Z-axis on the radar, the at least one reflector part is positioned at one of points at which imaginary lines, which run through the preset angles defined by the Z-axis and the radio waves emitted from the radar, meet the chamber part.

6. The apparatus of claim 4, wherein a distance from the radar to the at least one reflector part is defined as a preset distance and the plurality of reflector parts has different preset distances.

7. The apparatus of claim 6, wherein the preset distance r from the radar to the at least reflector part is within a distance range determined based on a formula of rₘᵢₙ≤nL±L/4≤rₘₐₓ, wherein rₘᵢₙ, is a minimum value of the preset distance r, and rₘₐₓ, is a maximum value of the preset distance r, n is constant multiples, L is distance resolution.

8. The apparatus of claim 7, wherein the distance resolution L is determined based on the formula of L≥C₀/2BWₜₓ, wherein C₀ represents a velocity of light and BW represents a band width of the radar.

9. The apparatus of claim 3, wherein the at least one reflector part includes a hemispherical reflector.

10. The apparatus of claim 1, further comprising:
a simulation part installed on a portion of the second inner surface of the chamber part that faces the first inner surface, the simulation part being configured to receive the radio waves from the radar and emit radio waves modified by a predetermined value.

11. The apparatus of claim 10, further comprising:
an absorbent installed on the inner surface of the chamber part and configured to absorb radio waves emitted from at least one of the radar, the at least one reflector part, and the simulation part.

12. The apparatus of claim 11, wherein the absorbent is installed on the second inner surface of the chamber part.

13. The apparatus of claim 1, further comprising:
an absorbent installed on the inner surface of the chamber part and configured to absorb radio waves emitted from at least one of the radar and the at least one reflector part.

14. The apparatus of claim 13, wherein the absorbent is installed on the second inner surface of the chamber part.

15. The apparatus of claim 13, wherein the absorbent includes a concave-convex surface having quadrangular pyramidal shapes repeatedly disposed.

16. The apparatus of claim 1, wherein the radar is disposed on the first inner surface and symmetric in a circumferential direction of the apparatus in a longitudinal axis of the apparatus.

17. The apparatus of claim 16, further comprising:
a simulation part installed on a portion of the second inner surface of the chamber part that faces the radar mounted on the first inner surface in the longitudinal axis on the radar.

18. The apparatus of claim 17, further comprising:
an absorbent installed on the inner surface of the chamber part and configured to absorb radio waves emitted from at least one of the radar, the at least one reflector part, and the simulation part.

19. The apparatus of claim 18, wherein the absorbent is installed on the second inner surface of the chamber part.
